(19) United States
(12) Patent Application Publication
(10) Pub. No.: US 2024/0373625 A1
(43) Pub. Date: Nov. 7, 2024

(54) MEMORY DEVICES WITH PARTIALLY MISALIGNED GAP LOCATIONS AND METHODS OF MANUFACTURING THEREOF

(71) Applicant: Taiwan Semiconductor Manufacturing Company, Ltd., Hsinchu (TW)

(72) Inventors: Kao-Cheng Lin, Hsinchu City (TW); Ku-Feng Lin, Hsinchu City (TW); Preciliano Ruiz, Jr., Hsinchu City (TW); Chien-Ying Chen, Hsinchu City (TW); Kazumasa Uno, Hsinchu City (TW)

(73) Assignee: Taiwan Semiconductor Manufacturing Company, Ltd., Hsinchu (TW)

(21) Appl. No.: 18/232,580

(22) Filed: Aug. 10, 2023

Related U.S. Application Data
(60) Provisional application No. 63/500,336, filed on May 5, 2023.

(51) Int. Cl. H10B 20/00

(52) U.S. Cl. CPC H10B 20/50

(57) ABSTRACT

A semiconductor device includes a memory array comprising a plurality of transistors arranged over a plurality of rows and a plurality of columns. The plurality of rows correspond to a plurality of active regions that continuously extend along a first lateral direction, respectively, and the plurality of columns correspond to a plurality of gate structures that discontinuously extend along a second lateral direction, respectively, the first lateral direction and the second lateral direction being perpendicular to each other. A first one of the gate structures comprising a first gap cutting the first gate structure and a second one of the gate structures comprising a second gap cutting the second gate structure are disposed immediately next to each other along the first lateral direction. The first gap and an extension of the second gap are offset from each other along the second lateral direction.

### CROSS-REFERENCE TO RELATED APPLICATION

This application claims priority to and the benefit of U.S. Provisional Application No. 63/500,336, filed May 5, 2023, entitled “METHOD TO ELIMINATE MISMATCH OF MEMORY BIT-LINE LEAKAGE WITH POLY EXTENSION EFFECT (PXE),” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example layout of a memory array, in accordance with some embodiments.

FIG. 2 illustrates an enlarged view of the layout shown in FIG. 1, in accordance with some embodiments.

FIG. 3 illustrates an equivalent circuit diagram of the memory array shown in FIG. 1, in accordance with some embodiments.

FIG. 4 illustrates plots of current levels present on different bit lines of the memory array shown in FIG. 1, in accordance with some embodiments.

FIG. 5 illustrates an example layout of another memory array, in accordance with some embodiments.

FIG. 6 illustrates an example layout of yet another memory array, in accordance with some embodiments.

FIG. 7 illustrates an example layout of yet another memory array, in accordance with some embodiments.

FIG. 8 illustrates an example layout of yet another memory array, in accordance with some embodiments.

FIG. 9 illustrates an example flow chart of a method for fabricating a memory array, in accordance with some embodiments.

FIG. 10 illustrates an example flow chart of another method for fabricating a memory array, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Read Only Memory (ROM) is a type of non-volatile memory used in computers and various other electronic devices. ROM arrays are semiconductor memory chip arrays with data permanently stored in the array. ROM arrays are made up of a plurality of ROM cells, each ROM cell includes a single transistor in an “on” or “off” state. Whether the transistor is in an “on” or “off” state depends on the inclusion of contact vias connecting an active region (e.g., source/drain region) of the transistor to a reference voltage VSS, for example, ground.

In accordance with increasingly shrunk technology nodes, ROM cells are commonly implemented as non-planar transistor structures (e.g., gate-all-around field-effect transistors, fin-based field-effect transistors, vertical field-effect transistors, etc.), as a result of their better drive current characteristics and sub-threshold leakage/matching performance compared to traditional planar transistor structures. When fabricating a ROM array with a plural number of ROM cells, a number of semiconductor structures extending in a first lateral direction and a number of conductive structures traversing the semiconductor structure are formed. As such, the ROM cells may be arranged over a number of rows (e.g., along the first lateral direction) and a number of columns (e.g., along the second lateral direction).

For example, each of the ROM cells is defined by an intersection of one of the semiconductor structures and a corresponding one of the conductive structures. Further, the conductive structure operatively serves as a gate of the ROM cell, and the portions of the semiconductor structure disposed on opposite sides of the conductive structure operatively serve as a drain and source of the ROM cell. The gate is electrically coupled to a corresponding word line (WL), and one of the source or drain is electrically coupled to a bit line (BL). Accordingly, the ROM array includes or is coupled to an array of the WLs and BLs.

To mitigate variation in a thickness of the gate, which disadvantageously create different voltage/current characteristics (e.g., Vₜₕ/Iₒₙ) in differently sized ROM arrays of a chip, each of the gates (e.g., the conductive structures) is typically cut to multiple discrete gate segments, with each of the gate segments traversing the same number (e.g., 4 or larger) of channels (e.g., the semiconductor structures). Alternatively stated, the gate segments have the same longitudinal length. In the existing circuits having one or more ROM arrays (sometimes referred to as ROM circuits), these gate segments are typically aligned with each other, i.e., having their cut ends aligned with one another. Such aligned gate segments commonly lead to issues that is referred to as a poly extension effect (PXE). In short, the ROM cell formed farther from the cut end typically shows a lower threshold voltage (Vₜₕ) than the ROM cell formed closer to the cut end. Consequently, a first BL connected to the farther ROM cell may present both higher conduction current (I₂ₒₙ) and leakage current (I_{2off}), while a second BL connected to the closer ROM may present both lower conduction current (lion) and leakage current (I_{1off}).

Such a mismatch between the current levels on different BLs generally complicates design of the corresponding circuit, and/or requires additional area. For example, adaptive reference current levels may be required to achieve similar read margins for the first BL and second BL, which requires additional circuits to generate the adaptive reference current levels. Otherwise, a read margin of the circuit may be significantly suppressed, as the read margin generally needs to take into account the worst case (where the read margin is estimated as the lower I₂ₒₙ minus the higher I_{1off}). The read margin can thus be significantly suppressed. Thus, the existing ROM circuit has not been entirely satisfactory in some aspects.

The present disclosure provides various embodiments of a semiconductor device including a Read Only Memory (ROM) array with a plural number of ROM cells. The ROM cells, each of which is implemented as a transistor, are formed by a number of active regions continuously extending along a first lateral direction and a number of gate structures discontinuously extending along a second lateral direction perpendicular to the first lateral direction. Each of the active regions has multiple portions overlaid or wrapped by the gate structures, respectively. For example, each of the ROM cells can be defined by a corresponding one of the active regions and a corresponding one of the gate structures. Further, along a lengthwise (the first lateral) direction of each of the active regions that is traversed by the gate structures, a row of the ROM cells can be formed. A plural number of such rows can be formed to extend along the first lateral direction. Along each row, a respective bit line (BL) electrically coupled to one of the source or drain of each of ROM cells disposed along that row, with the other of the source or drain coupled to ground (when storing a logic “1”) or being floating (when storing a logic “0”). The gate structures can be electrically coupled to a number of word lines, (WLs), respectively, which may extend along the same lengthwise direction (e.g., the second lateral direction) of the gate structures. As such, an array of access lines (e.g., the BLs and WLs) can be formed, with the BLs forming rows and the WLs forming columns of the array, respectively.

In accordance with some embodiments of the present disclosure, across the whole ROM array, the gate structures may be cut in a partially misaligned (e.g., zig-zag, staggered) manner, so as to cause “farther” ROM cells and “closer” ROM cells alternately arranged along each row (e.g., along each active region). The farther ROM cell and closer ROM cell, as used herein, may refer to ROM cells formed farther away from and closer to a cut end of the corresponding gate structure, respectively. The farther ROM cell may present a lower threshold voltage, while the closer ROM cell may present a higher threshold voltage, according to some embodiments. With the cut position configured in the partially misaligned manner, a distribution of respective threshold voltages of the ROM cells disposed along each row can thus be balanced or averaged out. For example, each BL may be electrically coupled to half of first ROM cells with a first (e.g., higher) threshold voltage and half of second ROM cells with a second (e.g., lower) threshold voltage, i.e., an equal distribution for the first and second threshold voltages. As such, the BLs (of all the rows) may share similar levels of conduction current (Iₒₙ) and leakage current (I_{off}), which may not require multiple or adaptive reference current levels to be provided. By averaging the lower leakage current (I_{1off}) and higher leakage current (I_{2off}), such a shared level of the leakage current can be lower than the higher leakage current (I_{2off}). In this way, even taking into account the worst case, a read margin can be increased (when compared to the existing ROM circuit as discussed above).

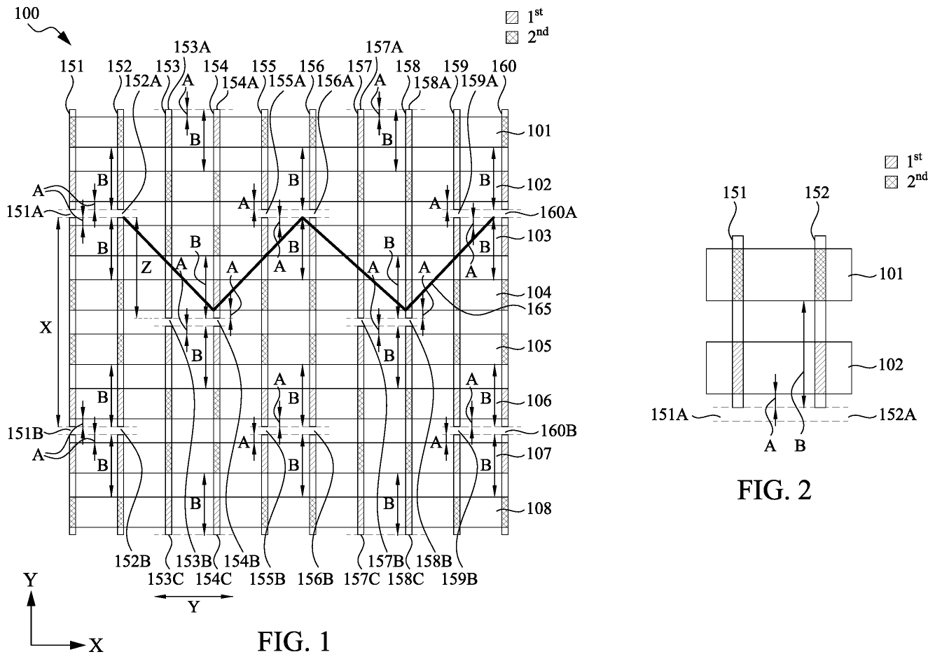

FIG. 1 illustrates an example layout 100 of a memory array, in accordance with some embodiments of the present disclosure. The layout 100 may be used to fabricate a ROM array (or/of a ROM circuit) that includes a number of ROM cells, in some embodiments. The ROM cells may each be implemented (e.g., fabricated) as a nanostructure transistor. Examples of such a nanostructure transistor include a gate-all-around (GAA FET) field-effect transistor, a fin-based field-effect transistor (FinFET), a vertical field-effect transistor, etc. However, it is understood that the layout 100 is not limited to fabricating nanostructure transistors. The layout 100 may be used to fabricate the ROM cells as any of various other types of transistor structures such as, for example, nanowire transistors, nanosheet transistors, etc., while remaining within the scope of the present disclosure.

As shown, the layout 100 includes patterns 101, 102, 103, 104, 105, 106, 107, and 108 extending along a first lateral direction (e.g., the X direction), and patterns 151, 152, 153, 154, 155, 156, 157, 158, 159, and 160 extending along a second lateral direction (e.g., the Y direction). The patterns 101 to 108 are each configured to form an active region (e.g., a fin structure, a well, a semiconductor stack having alternately stacked silicon and silicon germanium layers, etc., which is sometimes referred to as an oxide diffusion (OD) region) over a substrate, and the patterns 151 to 160 are each configured to form a gate structure (e.g., a polysilicon gate, a metal gate, etc.) over the active regions. Accordingly, the patterns 101 to 108 may each be referred to as an active region, and the patterns 151 to 160 may each be referred to as a gate structure.

The active regions 101 to 108 and the gate structures 151 to 160 can collectively form a number of transistors, each of which can be operatively configured as a ROM cell of a ROM array. In general, an intersection of each of the active regions 101 to 108 and a corresponding one of the gate structures 151 to 160 can operatively form a transistor. For example, the active region 101 and the gate structure 152 can form a transistor, in which the gate structure 152 functions as a gate terminal of the transistor, a portion of the active region 101 overlaid or wrapped by the gate structure 152 functions as a channel of the transistor, and portions of the active region 101 disposed on opposite sides of the gate structure 152 function as a source terminal and a drain terminal of the transistor, respectively.

In some embodiments, over an area on a substrate where the ROM array corresponding to the layout 100 is fabricated, the active regions 101 to 108 may each continuously extend along the X direction, while the gate structures 151 to 160 may each discontinuously extend along the Y direction. Further, each of the gate structures 151 to 160 may be cut or otherwise separated into a number of discrete gate segments. Stated another way, each of the gate structures 151 to 160 may have a number of gaps, each of which is configured to separate respective gate segments. As will be discussed below, such a gap is filled with an isolation material, and thus, the gate segments are electrically isolated from one another.

For example in FIG. 1, the gate structure 151 includes two gaps, 151A and 151B, to separate the gate structure 151 into three gate segments; the gate structure 152 includes gaps, 152A and 152B, to separate the gate structure 152 into three gate segments; the gate structure 153 includes three gaps, 153A, 153B, and 153C, to separate the gate structure 153 into four gate segments (two of which are shown); the gate structure 154 includes three gaps, 154A, 154B, and 154C, to separate the gate structure 154 into four gate segments (two of which are shown); the gate structure 155 includes two gaps, 155A and 155B, to separate the gate structure 155 into three gate segments; the gate structure 156 includes gaps, 156A and 156B, to separate the gate structure 156 into three gate segments; the gate structure 157 includes three gaps, 157A, 157B, and 157C, to separate the gate structure 157 into four gate segments (two of which are shown); the gate structure 158 includes three gaps, 158A, 158B, and 158C, to separate the gate structure 158 into four gate segments (two of which are shown); the gate structure 159 includes two gaps, 159A and 159B, to separate the gate structure 159 into three gate segments; the gate structure 160 includes gaps, 160A and 160B, to separate the gate structure 160 into three gate segments.

According to some embodiments of the present disclosure, these gaps, e.g., 151A-B, 152A-B, 153A-C, 154A-C, 155A-B, 156A-B, 157A-C, 158A-C, 159A-B, and 160A-B, may be configured to distribute across the array in a zig-zag matter. Specifically in FIG. 1, each of the gate segments of all the gate structures 151 to 160 may traverse four of the active regions 101 to 108 along the Y direction. Two of the adjacent gate structures 151 to 160 may have their gaps aligned along the X direction, and such a pair of adjacent gate structures may have their gaps shifted from the gaps of another pair of adjacent gate structures along the Y direction. As such, the aligned gaps (of a first pair of gate structures), the aligned gaps (of a second, next pair of gate structures), the aligned gaps (of a third, next pair of gate structures), and so on can form a course having abrupt alternate right and left turns, as indicated by symbolic line 165 in FIG. 1.

For example, in the pair of gate structures 151-152, the gaps 151A and 152A are aligned with each other along the X direction, and the gaps 151B and 152B are also aligned with each other along the X direction; in the next pair of gate structures 153-154, the gaps 153B and 154B are aligned with each other along the X direction; in the next pair of gate structures 155-156, the gaps 155A and 156A are aligned with each other along the X direction, and the gaps 155B and 156B are also aligned with each other along the X direction; in the next pair of gate structures 157-158, the gaps 157B and 157B are aligned with each other along the X direction; and in the next pair of gate structures 159-160, the gaps 159A and 160A are aligned with each other along the X direction, and the gaps 159B and 160B are also aligned with each other along the X direction.

Further, a projection or extension of the aligned gaps 153B and 154B (along the X direction) is shifted from the aligned gaps 151A and 152A and from the aligned gaps 151B and 152B along the Y direction; the projection or extension of the aligned gaps 153B and 154B (along the X direction) is shifted from the aligned gaps 155A and 156A and from the aligned gaps 155A and 156B along the Y direction. Stated another way, the aligned gaps 151A and 152A and the aligned gaps 151B and 152B are symmetric with respect to the aligned gaps 153B and 154B; and the aligned gaps 155A and 156A and the aligned gaps 155B and 156B are symmetric with respect to the aligned gaps 153B and 154B. Similarly, a projection or extension of the aligned gaps 157B and 158B (along the X direction) is shifted from the aligned gaps 155A and 156A and from the aligned gaps 155B and 156B along the Y direction; the projection or extension of the aligned gaps 157B and 158B (along the X direction) is shifted from the aligned gaps 159A and 160A and from the aligned gaps 159B and 160B along the Y direction. Stated another way, the aligned gaps 155A and 156A and the aligned gaps 155B and 156B are symmetric with respect to the aligned gaps 157B and 158B; and the aligned gaps 159A and 160A and the aligned gaps 159B and 160B are symmetric with respect to the aligned gaps 157B and 158B.

By cutting the gate structures 151 to 160 in such a zig-zag manner, each of the active regions 101 to 108, together with its corresponding gate segments, can form a mixture of first transistors and second transistors. Further, the first transistor is disposed closer to the cut end of a corresponding segment (e.g., spaced from a corresponding gap with a shorter distance “A,” as shown in FIG. 1), and the second transistor is disposed farther from the cut end of a corresponding segment (e.g., spaced from a corresponding gap with a longer distance “B,” as shown in FIG. 1). As such, the first transistor may have a first threshold voltage and the second transistor may have a second threshold voltage, in which the first threshold voltage is greater than the second threshold voltage.

FIG. 2 illustrates an enlarged view of a portion of the layout 100 that includes two of such first transistors and two of such second transistors. As shown, the first transistor (formed, e.g., by the active region 102 and the gate structure 151 or 152) has an edge of its active region 102 spaced from the gap 151A or 152A with the shorter distance A. The second transistor (formed, e.g., by the active region 101 and the gate structure 151 or 152) has an edge of its active region 101 spaced from the gap 151A or 152A with the longer distance B. Due to the PXE discussed above, the first transistor can present a higher threshold voltage than the second transistor. In FIGS. 1-2 (and the following figures), the gate structures of such first transistor and second transistor are filled with a pattern of diagonal stripes and a pattern of diamond grids, respectively.

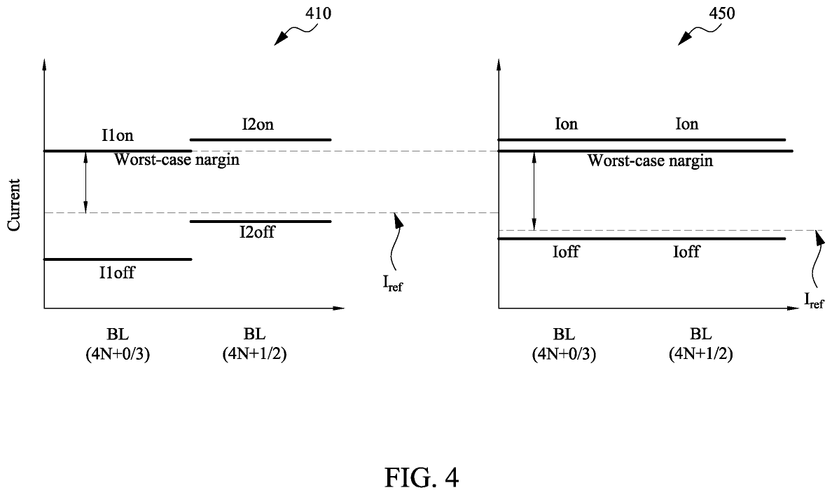

Referring again to FIG. 1, along each of the active regions 101 to 108, pairs of the first transistors and pairs of the second transistors are alternately arranged. Stated another way, a number of the first transistors and a number of the second transistors along each of the active regions 101 to 108 can be configured as equal to each other. Consequently, a distribution of respective threshold voltages of the first transistors and second transistors over the different active regions 101 to 108 can be the same, i.e., the active regions 101 to 108 corresponding to a common averaged threshold voltage. Using the active regions 103 and 104 as a representative example, along the active region 103, there may be three pairs of first transistors and three pairs of second transistors (with two shown); and, along the active region 104, there may be three pairs of second transistors and three pairs of first transistors (with two shown). As such, a first BL coupled to the transistors formed of the active region 103 can conduct first Iₒₙ and first I_{off}, and a second BL coupled to the transistors formed of the active region 104 can conduct second Iₒₙ and second I_{off}, wherein the first Iₒₙ is substantially equal to the second Iₒₙ and the first I_{off} is substantially equal to the second I_{off}, which will be further discussed with respect to FIG. 4.

Further, the configurations of the gaps 151A-B, 152A-B, 153A-C, 154A-C, 155A-B, 156A-B, 157A-C, 158A-C, 159A-B, and 160A-B may be represented (e.g., quantitated) by various parameters, X, Y, and Z, according to some embodiments. For example in FIG. 1, the number of active regions traversed by each gate segment may be represented by the parameter X (e.g., 4); the number of gate segments/structures with aligned gaps may be represented by the parameter Y (e.g., 2); and the number of active regions, across which the adjacent gaps are disposed along the Y direction, may be represented by the parameter Z (e.g., 2).

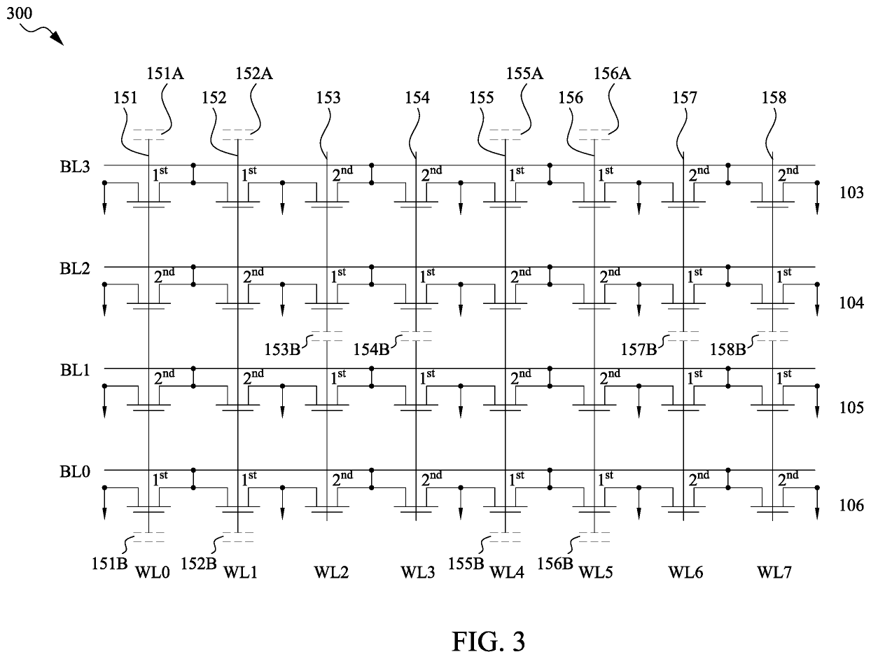

FIG. 3 illustrates an example circuit diagram 300 corresponding to a portion of the ROM array formed by the active regions 103 to 106 and the gate structures 151 to 158 (FIG. 1), in accordance with some embodiments of the present disclosure. This partial ROM array includes a plural number of ROM cells formed by the active regions 103 to 106 and the gate structures 151 to 158. Each of the ROM cells is implemented as a single transistor, with the corresponding gate structure and non-overlaid portions of the active corresponding active region serving as its gate terminal, drain terminal, and source terminal, respectively, in various embodiments of the present disclosure. However, it should be appreciated that the ROM cells may be implemented as other memory cell structures, while remaining within the scope of the present disclosure.

As indicated in FIG. 3, these ROM cells are formed over a number of columns and a number of rows, where word lines WL0, WL1, WL2, WL3, WL4, WL5, WL5, WL6, and WL7 are disposed in those columns, respectively, and bit lines BL0, BL1, BL2, and BL3 are disposed in those rows, respectively. Specifically, each of the word lines WL0 to WL7 is electrically coupled to the gate terminals of corresponding ROM cells (e.g., a corresponding discrete gate segment), and each of the bit lines BL0 to BL3 is electrically coupled to the source terminals or the drain terminals of corresponding ROM cells. In some embodiments, the ROM cells electrically connected by the same word line are disposed along the same column (sometimes referred to as “column cells”), and the ROM cells electrically connected by the same bit line are disposed along the same row (sometimes referred to as “row cells”).

For example, a segment of the word line WL0 is in electrical connection with the gate terminals of the ROM cells that are collectively defined by the gate segment cut between the gaps 151A and 151B; a segment of the word line WL1 is in electrical connection with the gate terminals of the ROM cells that are collectively defined by the gate segment cut between the gaps 152A and 152B; a first segment of the word line WL2 is in electrical connection with the gate terminals of the ROM cells that are collectively defined by the gate segment cut between the gaps 153A (not shown in FIG. 3) and 153B; a second segment of the word line WL2 is in electrical connection with the gate terminals of the ROM cells that are collectively defined by the gate segment cut between the gaps 153C (not shown in FIG. 3) and 153B; a first segment of the word line WL3 is in electrical connection with the gate terminals of the ROM cells that are collectively defined by the gate segment cut between the gaps 154A (not shown in FIG. 3) and 154B; a second segment of the word line WL3 is in electrical connection with the gate terminals of the ROM cells that are collectively defined by the gate segment cut between the gaps 154C (not shown in FIG. 3) and 154B; and so on.

According to some embodiments of the present disclosure, each set of the row cells have a mixture of the first transistors (with the first, higher threshold voltage, as shown in FIG. 2) and the second transistors (with the second, lower threshold voltage, as shown in FIG. 2). In some aspects, a percentage of the first transistors and a percentage of the second transistors may be identical or close to each other. Such a distribution of the first transistors and the second transistors are illustrated in the circuit diagram 300 (FIG. 3). In short, according to the zig-zag arranged gaps (e.g., 151B, 152B, 153B, 154B, 155B, 156B, 157B, 158B, etc.), the first transistors can form a zig-zig course along adjacent bit lines, and similarly, the second transistors can form another zig-zig course along these adjacent bit lines.

For example, along the bit line BL0, two of the first transistors, two of the second transistors, two of the first transistors, and two of the second transistors are alternately arranged from left to right; along the bit line BL1, two of the second transistors, two of the first transistors, two of the second transistors, and two of the first transistors are alternately arranged from left to right; along the bit line BL2, two of the second transistors, two of the first transistors, two of the second transistors, and two of the first transistors are alternately arranged from left to right; and along the bit line BL3, two of the first transistors, two of the second transistors, two of the first transistors, and two of the second transistors are alternately arranged from left to right. As such, along the bit lines BL0 and BL1, the first transistors (intersections of the gate structures 151-152 and the active region 106), the first transistors (intersections of the gate structures 153-154 and the active region 105), the first transistors (intersections of the gate structures 155-156 and the active region 106), and the first transistors (intersections of the gate structures 157-158 and the active region 105) form a first zig-zag course; and the second transistors (intersections of the gate structures 151-152 and the active region 105), the second transistors (intersections of the gate structures 153-154 and the active region 106), the second transistors (intersections of the gate structures 155-156 and the active region 105), and the second transistors (intersections of the gate structures 157-158 and the active region 106) form a second zig-zag course.

In this way, different sets of the row cells (i.e., along respective bit lines BLs) can have a common averaged threshold voltage, which causes different bit line BLs to conduct similar conduction current (Iₒₙ) and leakage current (I_{off}). In general, the conduction current (Iₒₙ) of a bit line BL refers to current flowing through one or more selected ROM cells that have been programmed to logic 1 (i.e., with its source and drain terminals electrically coupled to that bit line BL and ground, respectively), and the leakage current (I_{off}) refers to current flowing through one or more unselected ROM cells but electrically coupled to the same bit line BL.

FIG. 4 illustrates plots 410 and 450 representing example current level distributions along the BLs of the existing ROM circuit and the currently disclosed ROM circuit, respectively, in accordance with some embodiments of the present disclosure. In each of the plots 410 and 450, two sets of current levels (each having a current level of Iₒₙ and a current level of I_{off}) are illustrated for first bit lines BLs (e.g., 4N+0/3) and second bit lines BLs (e.g., 4N+½). The first bit line BLs include BL0, BL3 in FIG. 3 and the second bit line BLs include BL1, BL2 in FIG. 3.

As shown, in the plot 410 (i.e., the existing ROM circuit), the first bit lines BL show lower current levels of lion and I_{1off}, when compared to the second bit BLs that show higher current levels of I₂ₒₙ and I_{2off}. Consequently, a read margin in the worst case may be calculated as a difference of the current level between lion and a reference current level (I_{ref}) selected to be slightly higher than I_{2off}. In stark contrast, in the plot 450 (i.e., the disclosed ROM circuit), the first bit lines BL and second bit lines BL show similar (or common) current levels of Iₒₙ and I_{off}. As such, a read margin in the worst case, calculated as a difference between a current level slightly lower than the common Iₒₙ and a reference current level (I_{ref}) slightly higher than the common I_{off}, can be advantageously enlarged. Further, since all the bit lines BL of the disclosed ROM circuit share the common current levels of Iₒₙ and I_{off}, there may be one reference current level (I_{ref}) needed, which can simplify design and save area of the disclosed ROM circuit.

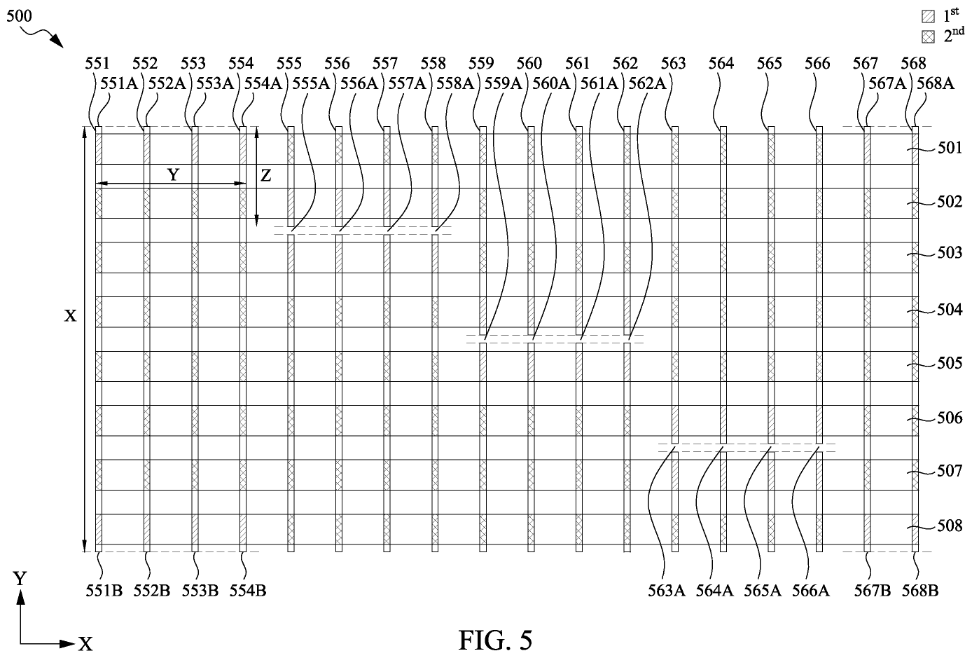

FIG. 5 illustrates an example layout 500 of another memory array, in accordance with some embodiments of the present disclosure. Similar to the layout 100 of FIG. 1, the layout 500 may be used to fabricate a ROM array (or/of a ROM circuit) that includes a number of ROM cells, in some embodiments. The ROM cells may each be implemented (e.g., fabricated) as a nanostructure transistor. Examples of such a nanostructure transistor include a gate-all-around (GAA FET) field-effect transistor, a fin-based field-effect transistor (FinFET), a vertical field-effect transistor, etc. In some embodiments, the layout 500 is similar to the layout 100 except that the layout 500 includes a different distribution of gaps cutting the gate structures. Thus, the following discussion of the layout 500 will be focused on the difference.

As shown, the layout 500 includes patterns 501, 502, 503, 504, 505, 506, 507, and 508 extending along a first lateral direction (e.g., the X direction), and patterns 551, 552, 553, 554, 555, 556, 557, 558, 559, 560, 561, 562, 563, 564, 565, 566, 567, and 568 extending along a second lateral direction (e.g., the Y direction). The patterns 501 to 508 are each configured to form an active region (e.g., a fin structure, a well, a semiconductor stack having alternately stacked silicon and silicon germanium layers, etc., which is sometimes referred to as an oxide diffusion (OD) region) over a substrate, and the patterns 551 to 568 are each configured to form a gate structure (e.g., a polysilicon gate, a metal gate, etc.) over the active regions. Accordingly, the patterns 501 to 508 may each be referred to as an active region, and the patterns 551 to 568 may each be referred to as a gate structure.

Over an area on a substrate where the ROM array corresponding to the layout 500 is fabricated, the active regions 501 to 508 may each continuously extend along the X direction, while the gate structures 551 to 568 may each discontinuously extend along the Y direction. Further, each of the gate structures 551 to 568 may be cut or otherwise separated into a number of discrete gate segments. Stated another way, each of the gate structures 551 to 568 may have a number of gaps, each of which is configured to separate respective gate segments. As will be discussed below, such a gap is filled with an isolation material, and thus, the gate segments are electrically isolated from one another.

For example in FIG. 5, the gate structure 551 includes two gaps, 551A and 551B, to separate the gate structure 551 into three gate segments; the gate structure 552 includes gaps, 552A and 552B, to separate the gate structure 552 into three gate segments; the gate structure 553 includes two gaps, 553A and 553B, to separate the gate structure 553 into three gate segments; the gate structure 554 includes gaps, 554A and 554B, to separate the gate structure 554 into three gate segments; the gate structure 555 includes one gap, 555A, to separate the gate structure 555 into two gate segments; the gate structure 556 includes one gap, 556A, to separate the gate structure 555 into two gate segments; the gate structure 557 includes one gap, 557A, to separate the gate structure 557 into two gate segments; the gate structure 558 includes one gap, 558A, to separate the gate structure 558 into two gate segments; the gate structure 559 includes one gap, 559A, to separate the gate structure 559 into two gate segments; the gate structure 560 includes one gap, 560A, to separate the gate structure 560 into two gate segments; the gate structure 562 includes one gap, 561A, to separate the gate structure 561 into two gate segments; the gate structure 562 includes one gap, 562A, to separate the gate structure 562 into two gate segments; the gate structure 563 includes one gap, 563A, to separate the gate structure 563 into two gate segments; the gate structure 564 includes one gap, 564A, to separate the gate structure 564 into two gate segments; the gate structure 565 includes one gap, 565A, to separate the gate structure 565 into two gate segments; the gate structure 566 includes one gap, 566A, to separate the gate structure 566 into two gate segments; the gate structure 567 includes two gaps, 567A and 567B, to separate the gate structure 567 into three gate segments; the gate structure 568 includes gaps, 568A and 568B, to separate the gate structure 568 into three gate segments.

According to some embodiments of the present disclosure, these gaps, e.g., 551A-B, 552A-B, 553A-B, 554A-B, 555A, 556A, 557A, 558A, 559A, 560A, 561A, 562A, 563A, 564A, 565A, 566A, 567A-B, 568A-B, may be configured to distribute across the array in a staggered matter. For example in FIG. 5, each of the gate segments of all the gate structures 551 to 568 may traverse eight of the active regions 501 to 508 along the Y direction. Four of the adjacent gate structures 551 to 568 may have their gaps aligned along the X direction, and such a quadruplet of adjacent gate structures may have their gaps shifted from the gaps of another quadruplet of adjacent gate structures along the Y direction. As such, the aligned gaps (of a first quadruplet of gate structures), the aligned gaps (of a second, next quadruplet of gate structures), the aligned gaps (of a third, next quadruplet of gate structures), and so on can form a course having a number of abrupt single-direction turns, as shown in FIG. 5.

For example, in the quadruplet of gate structures 551-554, the gaps 551A, 552A, 553A, and 554A are aligned with each other along the X direction, and the gaps 551B, 552B, 553B, and 554B are also aligned with each other along the X direction; in the next quadruplet of gate structures 555-558, the gaps 555A, 556A, 557A, and 558A are aligned with each other along the X direction; in the next quadruplet of gate structures 559-562, the gaps 559A, 560A, 561A, and 562A are aligned with each other along the X direction; and in the next quadruplet of gate structures 563-566, the gaps 563A, 564A, 565A, and 566A are aligned with each other along the X direction. Further, the aligned gaps 551A to 554A and the aligned gaps 551B to 554B are asymmetric with respect to any of the aligned gaps 555A to 558A, 559A to 562A, or 563A to 566A along the Y direction.

By cutting the gate structures 551 to 568 in such a staggered manner, each of the active regions 501 to 508, together with its corresponding gate segments, can form a mixture of the first transistors and the second transistors. As a recap, the first transistor is disposed closer to the cut end of a corresponding segment, and the second transistor is disposed farther from the cut end of a corresponding segment. As such, the first transistor may have a first threshold voltage and the second transistor may have a second threshold voltage, in which the first threshold voltage is greater than the second threshold voltage.

As indicated in FIG. 5, along each of the active regions 501 to 508, one quadruplet of the first transistors and three quadruplets of the second transistors are alternately arranged. Stated another way, along each of the active regions 101 to 108, there is one quadruplet of the first transistors every three contingent quadruplets of the second transistors. Consequently, a distribution of respective threshold voltages of the first transistors and second transistors over the different active regions 501 to 508 can be the same, i.e., the active regions 501 to 508 corresponding to a common averaged threshold voltage.

Using the active regions 503 and 504 as a representative example, along the active region 503, there may be one quadruplet of the second transistors, one quadruplet of the first transistors, and two quadruplets of the second transistors arranged in such an order; and along the active region 504, there may be two quadruplets of the second transistors, one quadruplet of the first transistors, and one quadruplet of the second transistors arranged in such an order. As such, a first BL coupled to the transistors formed of the active region 503 can conduct first Iₒₙ and first I_{off}, and a second BL coupled to the transistors formed of the active region 504 can conduct second Iₒₙ and second I_{off}, wherein the first Iₒₙ is substantially equal to the second Iₒₙ and the first I_{off} is substantially equal to the second I_{off}.

Further, the configurations of the gaps 551A-B, 552A-B, 553A-B, 554A-B, 555A, 556A, 557A, 558A, 559A, 560A, 561A, 562A, 563A, 564A, 565A, 566A, 567A-B, and 568A-B may be represented (e.g., quantitated) by various parameters, X, Y, and Z, according to some embodiments. For example in FIG. 5, the number of active regions traversed by each gate segment may be represented by the parameter X (e.g., 8); the number of gate segments/structures with aligned gaps may be represented by the parameter Y (e.g., 4); and the number of active regions, across which the adjacent gaps are disposed along the Y direction, may be represented by the parameter Z (e.g., 2).

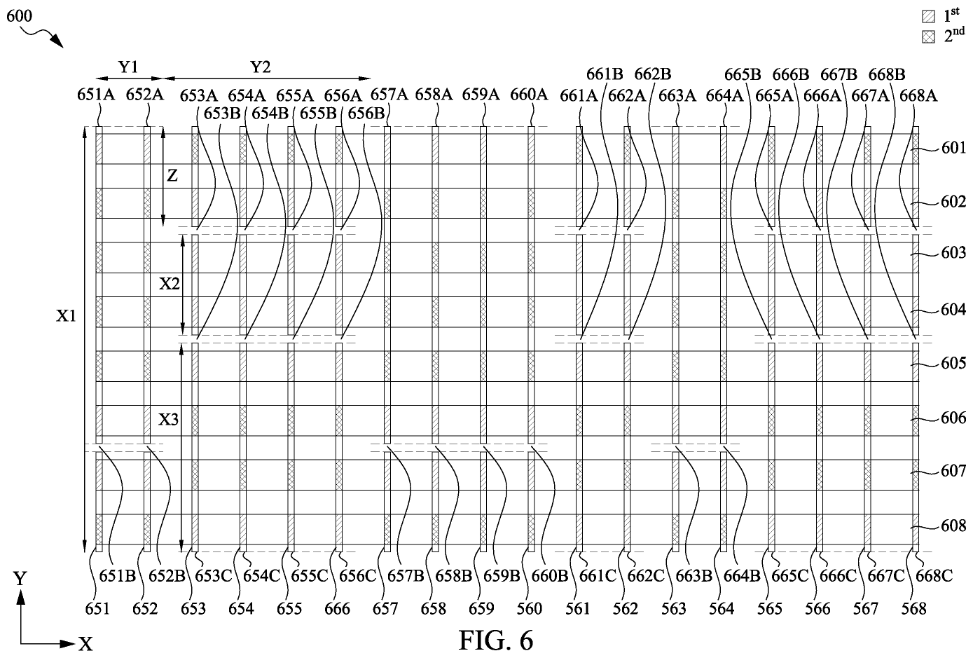

FIG. 6 illustrates an example layout 600 of yet another memory array, in accordance with some embodiments of the present disclosure. Similar to the layout 100 of FIG. 1, the layout 600 may be used to fabricate a ROM array (or/of a ROM circuit) that includes a number of ROM cells, in some embodiments. The ROM cells may each be implemented (e.g., fabricated) as a nanostructure transistor. Examples of such a nanostructure transistor include a gate-all-around (GAA FET) field-effect transistor, a fin-based field-effect transistor (FinFET), a vertical field-effect transistor, etc. In some embodiments, the layout 600 is similar to the layout 100 except that the layout 600 includes a different distribution of gaps cutting the gate structures. Thus, the following discussion of the layout 600 will be focused on the difference.

As shown, the layout 600 includes patterns 601, 602, 603, 604, 605, 606, 607, and 608 extending along a first lateral direction (e.g., the X direction), and patterns 651, 652, 653, 654, 655, 656, 657, 658, 659, 660, 661, 662, 663, 664, 665, 666, 667, and 668 extending along a second lateral direction (e.g., the Y direction). The patterns 601 to 608 are each configured to form an active region (e.g., a fin structure, a well, a semiconductor stack having alternately stacked silicon and silicon germanium layers, etc., which is sometimes referred to as an oxide diffusion (OD) region) over a substrate, and the patterns 651 to 668 are each configured to form a gate structure (e.g., a polysilicon gate, a metal gate, etc.) over the active regions. Accordingly, the patterns 601 to 608 may each be referred to as an active region, and the patterns 651 to 668 may each be referred to as a gate structure.

Over an area on a substrate where the ROM array corresponding to the layout 600 is fabricated, the active regions 601 to 608 may each continuously extend along the X direction, while the gate structures 651 to 668 may each discontinuously extend along the Y direction. Further, each of the gate structures 651 to 668 may be cut or otherwise separated into a number of discrete gate segments. Stated another way, each of the gate structures 651 to 668 may have a number of gaps, each of which is configured to separate respective gate segments. As will be discussed below, such a gap is filled with an isolation material, and thus, the gate segments are electrically isolated from one another.

For example in FIG. 6, the gate structure 651 includes two gaps, 651A and 651B, to separate the gate structure 651 into three gate segments; the gate structure 652 includes gaps, 652A and 652B, to separate the gate structure 652 into three gate segments; the gate structure 653 includes three gaps, 653A, 653B, and 653C, to separate the gate structure 653 into four gate segments; the gate structure 654 includes three gaps, 654A, 654B, and 654C, to separate the gate structure 654 into four gate segments; the gate structure 655 includes three gaps, 655A, 655B, and 655C, to separate the gate structure 655 into four gate segments; the gate structure 656 includes three gaps, 656A, 656B, and 656C, to separate the gate structure 656 into four gate segments; the gate structure 657 includes two gaps, 657A and 657B, to separate the gate structure 657 into three gate segments; the gate structure 658 includes two gaps, 658A and 658B, to separate the gate structure 658 into three gate segments; the gate structure 659 includes two gaps, 659A and 659B, to separate the gate structure 659 into three gate segments; the gate structure 660 includes two gaps, 660A and 660B, to separate the gate structure 660 into three gate segments; the gate structure 661 includes three gaps, 661A, 661B, and 661C, to separate the gate structure 661 into four gate segments; the gate structure 662 includes three gaps, 662A, 662B, and 662C, to separate the gate structure 662 into four gate segments; the gate structure 663 includes two gaps, 663A and 663B, to separate the gate structure 663 into three gate segments; the gate structure 664 includes two gaps, 664A and 664B, to separate the gate structure 664 into three gate segments; the gate structure 665 includes three gaps, 665A, 665B, and 665C, to separate the gate structure 665 into four gate segments; the gate structure 666 includes three gaps, 666A, 666B, and 666C, to separate the gate structure 666 into four gate segments; the gate structure 667 includes three gaps, 667A, 667B, and 667C, to separate the gate structure 667 into four gate segments; the gate structure 668 includes three gaps, 668A, 668B, and 668C, to separate the gate structure 668 into four gate segments.

According to some embodiments of the present disclosure, these gaps, e.g., 651A-B, 652A-B, 653A-C, 654A-C, 655A-C, 656A-C, 657A-B, 658A-B, 659A-B, 660A-B, 661A-C, 662A-C, 663A-B, 664A-B, 665A-C, 666A-C, 667A-C, 668A-C, may be configured to distribute across the array in a staggered matter. By cutting the gate structures 651 to 668 in such a staggered manner, each of the active regions 601 to 608, together with its corresponding gate segments, can form a mixture of the first transistors and the second transistors. As a recap, the first transistor is disposed closer to the cut end of a corresponding segment, and the second transistor is disposed farther from the cut end of a corresponding segment. As such, the first transistor may have a first threshold voltage and the second transistor may have a second threshold voltage, in which the first threshold voltage is greater than the second threshold voltage.

As indicated in FIG. 6, along each of the active regions 601 to 608, one pair of the first/second transistors, one quadruplet of the second/first transistors, one quadruplet of the first/second transistors, one pair of the second/first transistors, one pair of the first/second transistors, and one quadruplet of the second/first transistors are arranged. Consequently, a distribution of respective threshold voltages of the first transistors and second transistors over the different active regions 601 to 608 can be the same, i.e., the active regions 601 to 608 corresponding to a common averaged threshold voltage.

Using the active regions 603 and 604 as a representative example, along the active region 603, there may be one pair of the second transistors, one quadruplet of the first transistors, one quadruplet of the second transistors, one pair of the first transistors, one pair of the second transistors, and one quadruplet of the first transistors arranged in such an order; and along the active region 604, there may be one pair of the second transistors, one quadruplet of the first transistors, one quadruplet of the second transistors, one pair of the first transistors, one pair of the second transistors, and one quadruplet of the first transistors arranged in such an order. As such, a first BL coupled to the transistors formed of the active region 603 can conduct first Iₒₙ and first I_{off}, and a second BL coupled to the transistors formed of the active region 604 can conduct second Iₒₙ and second I_{off}, wherein the first Iₒₙ is substantially equal to the second Iₒₙ and the first I_{off} is substantially equal to the second I_{off}.

Further, the configurations of the gaps 651A-B, 652A-B, 653A-C, 654A-C, 655A-C, 656A-C, 657A-B, 658A-B, 659A-B, 660A-B, 661A-C, 662A-C, 663A-B, 664A-B, 665A-C, 666A-C, 667A-C, and 668A-C may be represented (e.g., quantitated) by various parameters, X₁, X₂, X₃, Y₁, Y₂, and Z, according to some embodiments. For example in FIG. 6, the number of active regions traversed by each gate segment may be represented by the parameters X₁, X₂, and X₃ (e.g., 6, 2, 4, respectively); the number of gate segments/structures with aligned gaps may be represented by the parameters Y₁ and Y₂ (e.g., 2 and 4, respectively); and the number of active regions, across which the adjacent gaps are disposed along the Y direction, may be represented by the parameter Z (e.g., 2).

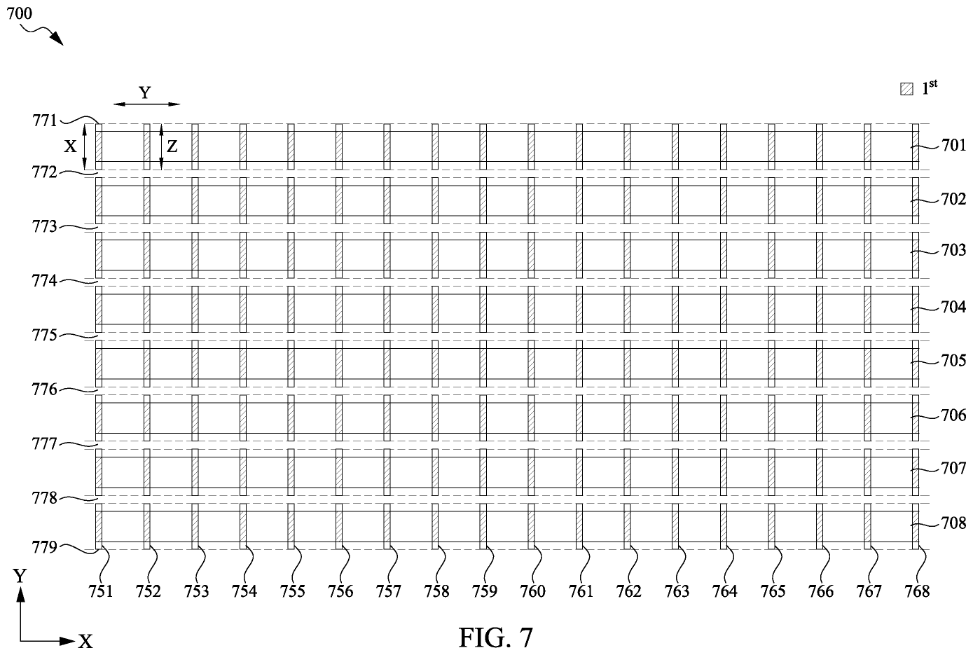

FIG. 7 illustrates an example layout 700 of yet another memory array, in accordance with some embodiments of the present disclosure. Similar to the layout 100 of FIG. 1, the layout 700 may be used to fabricate a ROM array (or/of a ROM circuit) that includes a number of ROM cells, in some embodiments. The ROM cells may each be implemented (e.g., fabricated) as a nanostructure transistor. Examples of such a nanostructure transistor include a gate-all-around (GAA FET) field-effect transistor, a fin-based field-effect transistor (FinFET), a vertical field-effect transistor, etc. Different from the layouts (100 of FIG. 1, 500 of FIG. 5, 600 of FIG. 6) discussed above, the layout 700 may have its gaps cutting respective gate structures aligned with each other, e.g., the respective cut segments of different gate structures are aligned with each other along a lateral direction perpendicular to the lengthwise direction of the gate structures. Accordingly, the following discussion of the layout 700 will be focused on the difference.

As shown, the layout 700 includes patterns 701, 702, 703, 704, 705, 706, 707, and 708 extending along a first lateral direction (e.g., the X direction), and patterns 751, 752, 753, 754, 755, 756, 757, 758, 759, 760, 761, 762, 763, 764, 765, 766, 767, and 768 extending along a second lateral direction (e.g., the Y direction). The patterns 701 to 708 are each configured to form an active region (e.g., a fin structure, a well, a semiconductor stack having alternately stacked silicon and silicon germanium layers, etc., which is sometimes referred to as an oxide diffusion (OD) region) over a substrate, and the patterns 751 to 768 are each configured to form a gate structure (e.g., a polysilicon gate, a metal gate, etc.) over the active regions. Accordingly, the patterns 701 to 708 may each be referred to as an active region, and the patterns 751 to 768 may each be referred to as a gate structure.

Over an area on a substrate where the ROM array corresponding to the layout 700 is fabricated, the active regions 701 to 708 may each continuously extend along the X direction, while the gate structures 751 to 768 may each discontinuously extend along the Y direction. Further, each of the gate structures 751 to 768 may be cut or otherwise separated into a number of discrete gate segments. Stated another way, each of the gate structures 751 to 768 may have a number of gaps, each of which is configured to separate respective gate segments. Further, the gaps across different gate structures may be aligned with one another along the X direction, and each of the gate segments may traverse a single corresponding one of the active regions. As will be discussed below, such a gap is filled with an isolation material, and thus, the gate segments are electrically isolated from one another.

For example in FIG. 7, the gate structures 751 to 768 share a number of gaps 771, 772, 773, 774, 775, 776, 777, 778, and 779. The gaps 771 to 779 each continuously extend across the gate structures 751 to 768. Each of the gaps 771 to 779 is configured to separate a first gate segment of a corresponding one of the gate structures 751 to 758 and a second gate segment of the corresponding gate structure. The first gate segment traverses a first one of the active regions 701 to 708, and the second gate segment traverses a second one of the active regions 701 to 708. The first active region is disposed immediately next to the second active region along the Y direction. As such, the ROM cells formed by the active regions 701 to 708 and the gate structures 751 to 768 may all be the first transistors, as indicated in FIG. 7. Accordingly, BLs coupled to the transistors formed of the active regions 701 to 707 can conduct similar conduction current Iₒₙ and similar leakage current I_{off}.

Further, the configurations of the gaps 771 to 779 may be represented (e.g., quantitated) by various parameters, X, Y, and Z, according to some embodiments. For example in FIG. 7, the number of active regions traversed by each gate segment may be represented by the parameter X (e.g., 1); the number of gate segments/structures with aligned gaps may be represented by the parameter Y (e.g., 1); and the number of active regions, across which the adjacent gaps are disposed along the Y direction, may be represented by the parameter Z (e.g., 1).

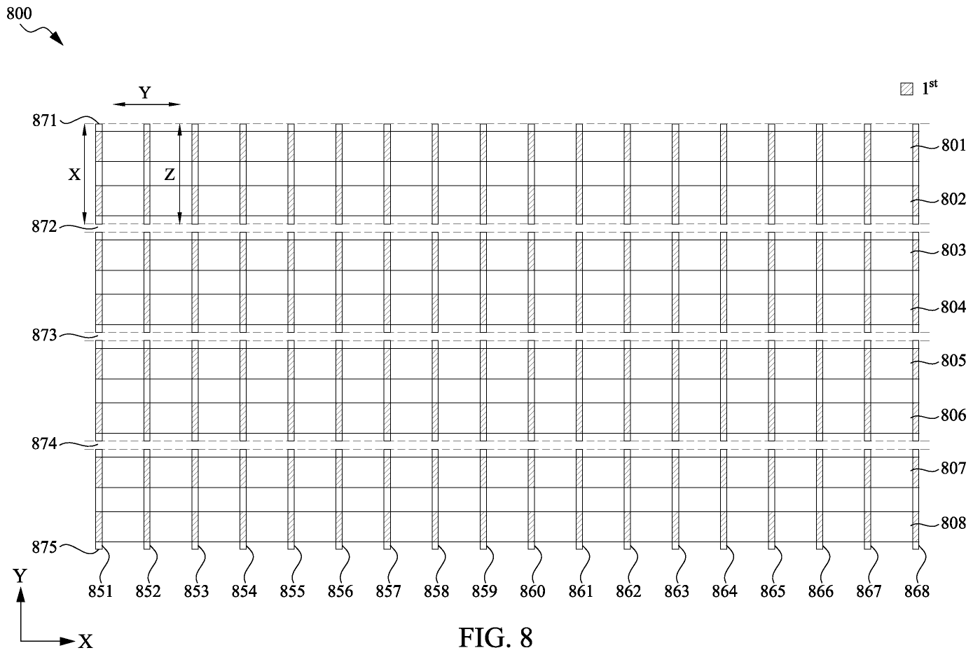

FIG. 8 illustrates an example layout 800 of yet another memory array, in accordance with some embodiments of the present disclosure. Similar to the layout 100 of FIG. 1, the layout 800 may be used to fabricate a ROM array (or/of a ROM circuit) that includes a number of ROM cells, in some embodiments. The ROM cells may each be implemented (e.g., fabricated) as a nanostructure transistor. Examples of such a nanostructure transistor include a gate-all-around (GAA FET) field-effect transistor, a fin-based field-effect transistor (FinFET), a vertical field-effect transistor, etc. Different from the layouts (100 of FIG. 1, 500 of FIG. 5, 600 of FIG. 6) discussed above, the layout 800 may have its gaps cutting respective gate structures aligned with each other, e.g., the respective cut segments of different gate structures are aligned with each other along a lateral direction perpendicular to the lengthwise direction of the gate structures. Accordingly, the following discussion of the layout 800 will be focused on the difference.

As shown, the layout 800 includes patterns 801, 802, 803, 804, 805, 806, 807, and 808 extending along a first lateral direction (e.g., the X direction), and patterns 851, 852, 853, 854, 855, 856, 857, 858, 859, 860, 861, 862, 863, 864, 865, 866, 867, and 868 extending along a second lateral direction (e.g., the Y direction). The patterns 801 to 808 are each configured to form an active region (e.g., a fin structure, a well, a semiconductor stack having alternately stacked silicon and silicon germanium layers, etc., which is sometimes referred to as an oxide diffusion (OD) region) over a substrate, and the patterns 851 to 868 are each configured to form a gate structure (e.g., a polysilicon gate, a metal gate, etc.) over the active regions. Accordingly, the patterns 801 to 808 may each be referred to as an active region, and the patterns 851 to 868 may each be referred to as a gate structure.

Over an area on a substrate where the ROM array corresponding to the layout 800 is fabricated, the active regions 801 to 808 may each continuously extend along the X direction, while the gate structures 851 to 868 may each discontinuously extend along the Y direction. Further, each of the gate structures 851 to 868 may be cut or otherwise separated into a number of discrete gate segments. Stated another way, each of the gate structures 851 to 868 may have a number of gaps, each of which is configured to separate respective gate segments. Further, the gaps across different gate structures may be aligned with one another along the X direction, and each of the gate segments may traverse a single corresponding one of the active regions. As will be discussed below, such a gap is filled with an isolation material, and thus, the gate segments are electrically isolated from one another.

For example in FIG. 8, the gate structures 851 to 868 share a number of gaps 871, 872, 873, 874, and 875. The gaps 871 to 875 each continuously extend across the gate structures 851 to 868. Each of the gaps 871 to 875 is configured to separate a first gate segment of a corresponding one of the gate structures 851 to 858 and a second gate segment of the corresponding gate structure. The first gate segment traverses a first pair of the active regions 801 to 808, and the second gate segment traverses a second pair of the active regions 801 to 808. The first pair of active regions are disposed immediately next to the second pair of active regions along the Y direction. As such, the ROM cells formed by the active regions 801 to 808 and the gate structures 851 to 868 may all be the first transistors, as indicated in FIG. 8. Accordingly, BLs coupled to the transistors formed of the active regions 801 to 807 can conduct similar conduction current Iₒₙ and similar leakage current I_{off}.

Further, the configurations of the gaps 871 to 875 may be represented (e.g., quantitated) by various parameters, X, Y, and Z, according to some embodiments. For example in FIG. 8, the number of active regions traversed by each gate segment may be represented by the parameter X (e.g., 3); the number of gate segments/structures with aligned gaps may be represented by the parameter Y (e.g., 1); and the number of active regions, across which the adjacent gaps are disposed along the Y direction, may be represented by the parameter Z (e.g., 3).

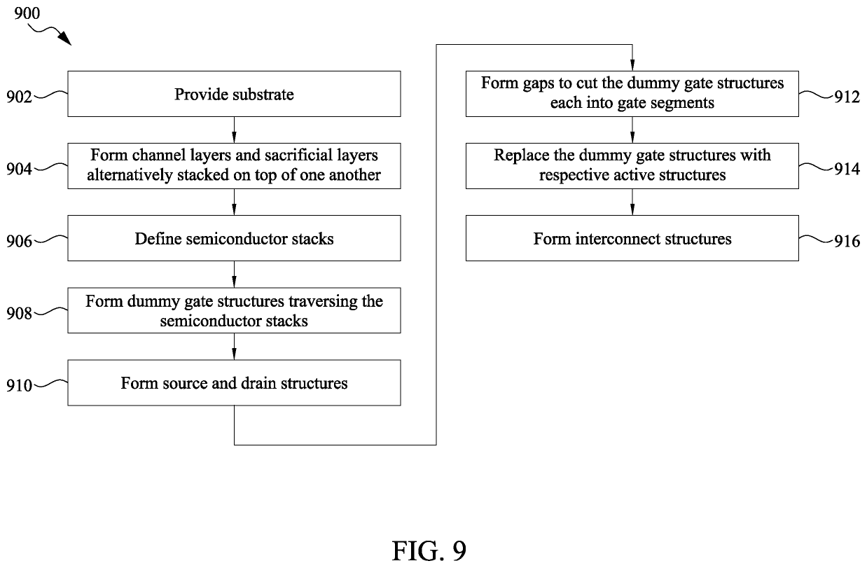

FIG. 9 illustrates a flow chart of an example method 900 for forming a memory array that includes a number of bit lines BLs, in accordance with various embodiments. Further, the bit lines BLs are coupled to respectively different sets of memory cells. These different sets of memory cells may present a common averaged threshold voltage, which can advantageously enlarge a read margin of the memory array and simplifies its design. In some embodiments, the memory cells may each operatively serve as a ROM cell, and may each be configured in a GAA FET structure. However, it should be understood that the ROM cells may each be configured in any of various other transistor structures such as, for example, a planar complementary metal-oxide-semiconductor (CMOS) FET structure, a FinFET structure, etc., while remaining within the scope of the present disclosure.

It is noted that the method 900 is merely an example, and is not intended to limit the present disclosure. Accordingly, it should be understood that additional operations may be provided before, during, and/or after the method 900, and that some other operations may only be briefly described herein. Some operations of the method 900 may be associated with the components shown in FIGS. 1-8, and thus, the following discussions of the method 900 may sometimes refer to FIGS. 1-8.

In brief overview, the method 900 starts with operation 902 of providing a substrate. The method 900 proceeds to operation 904 of forming channel layers and sacrificial layers alternatively stacked on top of one another. The method 900 proceeds to operation 906 of defining a number of semiconductor stacks. The method 900 proceeds to operation 908 of forming a number of dummy gate structures traversing the semiconductor stacks. The method 900 proceeds to operation 910 of forming source and drain structures. The method 900 proceeds to operation 912 of forming a number of gaps to cut the dummy gate structures each into a number of gate segments. The method 900 proceeds to operation 914 of replacing the dummy gate structures with respective active structures. The method 900 proceeds to operation 916 of forming interconnect structures.

The method 900 starts with operation 902 of providing a substrate, in accordance with some embodiments. The substrate may be a semiconductor substrate, such as a bulk semiconductor, or the like, which may be doped (e.g., with a p-type or an n-type dopant) or undoped. The substrate may be a wafer, such as a silicon wafer. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The method 900 proceeds to operation 904 of forming, over the substrate, a number of channel layers and a number of sacrificial layers alternatively stacked on top of one another, in accordance with some embodiments. For example, one of the channel layers is disposed over one of the sacrificial layers, then another one of the sacrificial layers is disposed over the channel layer, so on and so forth. Any number of alternately disposed sacrificial and channel layers can be formed over the substrate, as a stack of blanket layers (hereinafter “blanket stack”).

The channel layers and sacrificial layers of such a blanket stack may have different compositions. In various embodiments, the channel layers and sacrificial layers have compositions that provide for different oxidation rates and/or different etch selectivity between these two types of layers. In an embodiment, the sacrificial layers may each include silicon germanium (Si₁₋ₓGeₓ), and the channel layers may each include silicon (Si). In an embodiment, each of the channel layers is silicon that may be undoped or substantially dopant-free (i.e., having an extrinsic dopant concentration from about 0 cm⁻³ to about 1×10¹⁷ cm⁻³), where for example, no intentional doping is performed when forming the channel layers (e.g., of silicon). The channel layers and sacrificial layers can be epitaxially grown from the semiconductor substrate. For example, each of the channel layers and sacrificial layers may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the semiconductor substrate extends upwardly, resulting in the channel layers and sacrificial layers having the same crystal orientation with the semiconductor substrate.

The method 900 proceeds to operation 906 of defining a number of semiconductor stacks in parallel with one another, in accordance with some embodiments. These semiconductor stacks may be defined according to the active regions (active region patterns) of the layouts 100, 500, 600, 700, and 800 described in FIGS. 1, 5, 6, 7, and 8, respectively. As such, the semiconductor stacks may be formed in parallel with one another, i.e., extending along the same lateral direction (e.g., the X direction) and spaced from one another along another lateral direction (e.g., the Y direction).

Upon growing the blanket stack on the semiconductor substrate, the blanket stack may be patterned to form the semiconductor stacks. Each of the semiconductor stacks is elongated along a first lateral direction and includes a stack of patterned sacrificial layers and channel layers interleaved with each other. The semiconductor stacks are formed by patterning the blanket stack using, for example, photolithography and etching techniques.

For example, a mask layer (which can include multiple layers such as, for example, a pad oxide layer and an overlying hardmask layer) is formed over the topmost layer of the blanket stack. The pad oxide layer may be a thin film comprising silicon oxide formed, for example, using a thermal oxidation process. The pad oxide layer may act as an adhesion layer between the topmost layer and the hardmask layer. In some embodiments, the hardmask layer may include silicon nitride, silicon oxynitride, silicon carbonitride, the like, or combinations thereof. In some other embodiments, the hardmask layer may include a material similar as a material of the channel/sacrificial layers such as, for example, Si_{1-y}Ge_{y}, Si, etc., in which the molar ratio (y) may be different from or similar to the molar ratio (x) of the sacrificial layers. The hardmask layer may be formed over the stack (i.e., before pattering the stack) using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask.

The patterned mask can be subsequently used to pattern exposed portions of the blanket stack to form the semiconductor stacks, thereby defining trenches (or openings) between adjacent semiconductor stacks. When multiple semiconductor stacks are formed, each of such trenches may be disposed between any adjacent ones of the semiconductor stacks. In some embodiments, the semiconductor stacks are formed by etching the layers of the blanket stack in the trenches using, for example, reactive ion etching (RIE), neutral beam etching (NBE), the like, or combinations thereof. The etching may be anisotropic. In some embodiments, the trenches may be strips (when viewed from the top) parallel to each other, and closely spaced with respect to each other. In some embodiments, the trenches may be continuous and surround the respective semiconductor stacks.

The method 900 proceeds to operation 908 of forming a number of dummy gate structures traversing the semiconductor stacks, in accordance with some embodiments. These dummy gate structures may be defined according to the gate structures (gate structure patterns) of the layouts 100, 500, 600, 700, and 800 described with respect to FIGS. 1, 5, 6, 7, and 8, respectively, that have not been cut. As such, the gate structures may be formed in parallel with one another, i.e., extending along the same lateral direction (e.g., the Y direction) and spaced from one another along another lateral direction (e.g., the X direction).

The dummy gate structures are formed over each of the semiconductor stacks. The dummy gate structures, in parallel with each other, extend along a lateral direction perpendicular to the lengthwise direction of the semiconductor stacks. As such, each of the dummy gate structures can straddle or otherwise traverse respective portions of the semiconductor stacks. That is, a top surface and sidewalls of each of the semiconductor stacks, at least in part, are in contact with a corresponding one of the dummy gate structures.

The dummy gate structures may each include a dummy gate dielectric and a dummy gate, which are not shown separately for purpose of clarity. To form the dummy gate structure, a dielectric layer may be formed over the semiconductor stacks. The dielectric layer may be, for example, silicon oxide, silicon nitride, silicon oxynitride, silicon carbide, silicon carbonitride, silicon oxycarbonitride, silicon oxycarbide, multilayers thereof, or the like, and may be deposited or thermally grown.

A gate layer is formed over the dielectric layer, and a mask layer is formed over the gate layer. The gate layer may be deposited over the dielectric layer and then planarized, such as by a CMP. The mask layer may be deposited over the gate layer. The gate layer may be formed of, for example, polysilicon, although other materials may also be used. The mask layer may be formed of, for example, silicon nitride or the like. After the layers (e.g., the dielectric layer, the gate layer, and the mask layer) are formed, the mask layer may be patterned using suitable lithography and etching techniques. Next, the pattern of the mask layer may be transferred to the gate layer and the dielectric layer by a suitable etching technique to form the dummy gate structures.

Upon forming the dummy gate structures, a gate spacer may be formed on opposing sidewalls of a corresponding one of the dummy gate structures. The gate spacer may be a low-k spacer and may be formed of a suitable dielectric material, such as silicon oxide, silicon oxycarbonitride, or the like. Any suitable deposition method, such as thermal oxidation, chemical vapor deposition (CVD), or the like, may be used to form the gate spacer.

The method 900 proceeds to operation 910 of forming source and drain structures, in accordance with some embodiments. The dummy gate structures (together with their corresponding gate spacers) can serve as a mask to recess (e.g., etch) the non-overlaid portions of each of the semiconductor stacks, which results in the semiconductor stacks having respective remaining portions of the sacrificial layers and channel layers alternately stacked on top of one another. As a result, source and drain recesses can be formed on opposite sides of each of the dummy gate structures.

The recessing step to form the source and drain recesses may be configured to have at least some anisotropic etching characteristic. For example, the recessing step can include a plasma etching process, which can have a certain amount of anisotropic characteristic. In such a plasma etching process (including radical plasma etching, remote plasma etching, and other suitable plasma etching processes), gas sources such as chlorine (Cl₂), hydrogen bromide (HBr), carbon tetrafluoride (CF₄), fluoroform (CHF₃), difluoromethane (CH₂F₂), fluoromethane (CH₃F), hexafluoro-1,3-butadiene (C₄F₆), boron trichloride (BCl₃), sulfur hexafluoride (SF₆), hydrogen (H₂), nitrogen trifluoride (NF₃), and other suitable gas sources and combinations thereof can be used with passivation gases such as nitrogen (N₂), oxygen (O₂), carbon dioxide (CO₂), sulfur dioxide (SO₂), carbon monoxide (CO), methane (CH₄), silicon tetrachloride (SiCl₄), and other suitable passivation gases and combinations thereof. Moreover, for the recessing step, the gas sources and/or the passivation gases can be diluted with gases such as argon (Ar), helium (He), neon (Ne), and other suitable dilutive gases and combinations thereof to control the above-described etching rates.

Prior to forming the source and drain structures, end portions of the sacrificial layers can be removed (e.g., etched) using a “pull-back” process with a pull-back distance. In an example where the channel layers include Si, and the sacrificial layers include SiGe, the pull-back process may include a hydrogen chloride (HCl) gas isotropic etch process, which etches SiGe without attacking Si. As such, the Si layers (nanostructures) may remain substantially intact during this pull-back process. Consequently, a pair of recesses can be formed on the ends of each of the sacrificial layers, with respect to the neighboring channel layers. Next, such recesses on the ends of each sacrificial layer can be filled with a dielectric material to form inner spacers. The dielectric material for the inner spacers may include silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacer for transistors.

Next, the source and drain structures can be formed in the source and drain recesses, respectively. The source and drain structures are formed by epitaxially growing a semiconductor material (e.g., from the channel layers of the semiconductor stack) in the source and drain recesses using suitable methods such as metal-organic CVD (MOCVD), molecular beam epitaxy (MBE), liquid phase epitaxy (LPE), vapor phase epitaxy (VPE), selective epitaxial growth (SEG), the like, or combinations thereof.

Following the formation of the source and drain structures, an inter-layer dielectric (ILD) can be formed to overlay at least the source and drain structures. The ILD is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. After the ILD is formed, an optional dielectric layer (not shown) is formed over the ILD. The dielectric layer can function as a protection layer to prevent or reduces the loss of the ILD in subsequent etching processes. The dielectric layer may be formed of a suitable material, such as silicon nitride, silicon carbonitride, or the like, using a suitable method such as CVD, PECVD, or FCVD. After the dielectric layer is formed, a planarization process, such as a CMP process, may be performed to achieve a level top surface for the dielectric layer.

The method 900 proceeds to operation 912 of forming a number of gaps to cut the dummy gate structures each into a number of gate segments, in accordance with some embodiments. These gaps may be defined according to the gaps 151A-B, 152A-B, 153A-C, 154A-C, 155A-B, 156A-B, 157A-C, 158A-C, 159A-B, and 160A-B of the layout 100, the gaps 551A-B, 552A-B, 553A-B, 554A-B, 555A, 556A, 557A, 558A, 559A, 560A, 561A, 562A, 563A, 564A, 565A, 566A, 567A-B, 568A-B of the layout 500, the gaps 651A-B, 652A-B, 653A-C, 654A-C, 655A-C, 656A-C, 657A-B, 658A-B, 659A-B, 660A-B, 661A-C, 662A-C, 663A-B, 664A-B, 665A-C, 666A-C, 667A-C, 668A-C of the layout 600, the gaps 771 to 779 of the layout 700, and the gaps 871 to 875 of the layout 800 described in FIGS. 1, 5, 6, 7, and 8, respectively. As such, the gate structures may each be cut or otherwise separated into a number of discrete gate segments that are spaced from one another along the lengthwise direction of the gate structure (e.g., the Y direction).

The gaps may be formed by at least one vertical etching process in the direction towards the substrate to remove portions of the dummy gate structures according to the gap positions defined in the layouts 100, 500, 600, 700, and 800 discussed above. Any suitable etching process, such as a dry etching process or a wet etching process, can be used to remove desired portions of the dummy gate structures. For instance, the etching process can involve at least one of transformer coupled plasma (TCP) or inductively coupled plasma (ICP) etching technique(s) for directionally removing the dummy gate structures. Following the formation of the gaps, such gaps are filled with an isolation material such as, for example, silicon oxide, silicon nitride, silicon oxynitride, silicon carbide, silicon carbonitride, silicon oxycarbonitride, silicon oxycarbide, or combinations thereof.

For example, the etching process can include or involve directional etching to control the bowing, such as by configuring at least one of oxygen (O₂) flush time (or rate), argon (Ar) sputter time (or rate), and/or the cycle of at least one of SiCl₄, nitrogen gas (N₂), O₂, and/or chlorine, silane (SiH₄), among others. For instance, the gas used in the etching process can involve using an O₂ flush of 100-200 standard cubic centimeter per minute (sccm), Ar sputter including carbon tetrafluoride (CF₄) of 0-100 about sccm and Ar of about 500-1000 sccm, the cycle including SiCl₄ of about 0-50 sccm, N₂ of about 0-100 sccm, O₂ of about 0-100 sccm, and Cl₂ of about 100-500 sccm, etc. Hence, the etching process can minimize or control the bowing of the dummy gate structures, providing a comparatively vertical or linear side surface of the dummy gate structures. This can prevent any unintended short-circuits, current leakage, or logic circuits that do not function properly.

The method 900 proceeds to operation 914 of replacing the dummy gate structures with respective active structures, in accordance with some embodiments. After the gaps are filled with the isolation material, the dummy gate structures, and the (remaining) sacrificial layers may be concurrently removed. In various embodiments, the dummy gate structures and the sacrificial layers can be removed by applying a selective etch (e.g., a hydrochloric acid (HCl)), while leaving the channel layers substantially intact. After the removal of the dummy gate structures, a gate trench, exposing respective sidewalls of each of the channel layers may be formed. After the removal of the sacrificial layers (which can further extend the gate trench), respective bottom surface and/or top surface of each of the channel layers may be exposed. Consequently, a full circumference of each of the channel layers can be exposed. Next, the active gate structure are formed to wrap around each of the channel layers.

The active gate structures each include a gate dielectric and a gate metal (which are not separately shown for the sake of clarity), in some embodiments. The gate dielectric can wrap around each of the channel layers, e.g., the top and bottom surfaces and sidewalls). The gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The gate dielectric may include a stack of multiple high-k dielectric materials. The gate dielectric can be deposited using any suitable method, including, for example, molecular beam deposition (MBD), atomic layer deposition (ALD), PECVD, and the like. In some embodiments, the gate dielectric may optionally include a substantially thin oxide (e.g., SiOₓ) layer, which may be a native oxide layer formed on the surface of each of the channel layers.

The gate metal may include a stack of multiple metal materials. For example, the gate metal may be a p-type work function layer, an n-type work function layer, multi-layers thereof, or combinations thereof. The work function layer may also be referred to as a work function metal. Example p-type work function metals that may include TiN, TaN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAlC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a target threshold voltage is achieved in the device that is to be formed. The work function layer(s) may be deposited by CVD, physical vapor deposition (PVD), ALD, and/or other suitable process.

Upon forming the active gate structures, a number of ROM cells (e.g., transistors) can be formed. Such ROM cells may be formed as an array, in which the ROM cells are arranged across a number of rows (e.g., extending in the X direction) and a number of columns (e.g., extending in the Y direction). According to various embodiments of the present disclosure, the ROM cells arranged along the same row are referred to as row cells, and the ROM cells arranged along the same column are referred to as column cells.

The method 900 proceeds to operation 916 of forming interconnect structures, in accordance with some embodiments. These interconnect structures may be formed across multiple metallization layers disposed over the components previously formed, e.g., the active gate structures, the source and drain structures, etc. A first set of interconnect structures functioning as bit lines BLs (each electrically coupled to the drain or source structures of corresponding row cells) are formed in a first metallization layer, and a second set of interconnect structures functioning as word lines WLs (each electrically coupled to the gate segments of corresponding column cells) are formed in a second metallization layer disposed above the first metallization layer. For example, the bit lines BL are formed as M1 tracks extending in the same direction as the semiconductor stacks (e.g., the X direction), and the word lines are formed as M2 tracks extending in the same direction as the gate structures/segments (e.g., the Y direction).

The interconnect structures (formed of one or more metal materials, e.g., copper) may be formed based on a single damascene process, a dual damascene process, a reactive ion etching process, and other suitable processes. For example, in a damascene process, one or more trenches/openings are formed in an inter-metal dielectric (IMD), and then refilled with one or more metal materials to form the interconnect structures. Such an ID is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD.

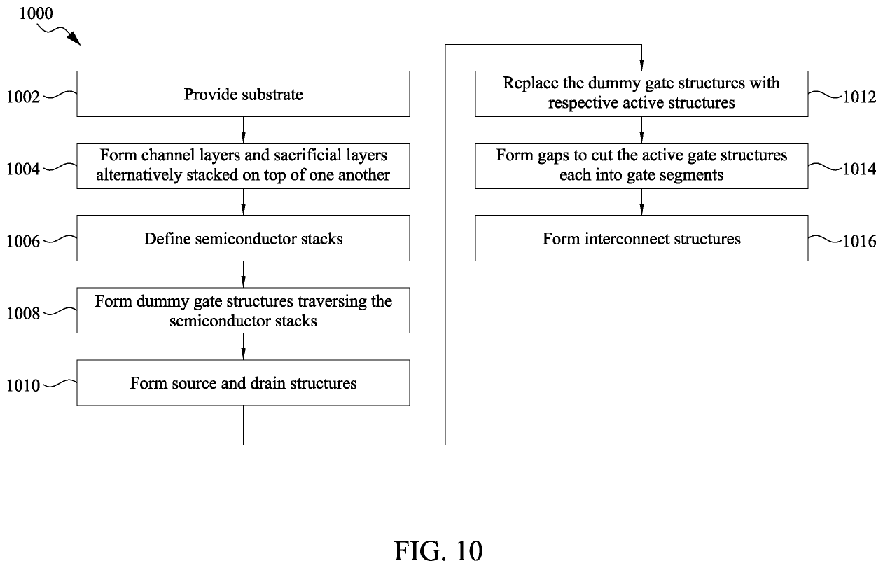

FIG. 10 illustrates a flow chart of another example method 1000 for forming a memory array that includes a number of bit lines BLs, in accordance with various embodiments. Further, the bit lines BLs are coupled to respectively different sets of memory cells. These different sets of memory cells may present a common averaged threshold voltage, which can advantageously enlarge a read margin of the memory array and simplifies its design. In some embodiments, the memory cells may each operatively serve as a ROM cell, and may each be configured in a GAA FET structure. However, it should be understood that the ROM cells may each be configured in any of various other transistor structures such as, for example, a planar complementary metal-oxide-semiconductor (CMOS) FET structure, a FinFET structure, etc., while remaining within the scope of the present disclosure.

It is noted that the method 1000 is substantially similar to the method 900 except for the sequence. Accordingly, the method 1000 will be briefly described as follows. For example, the method 1000 starts with operation 1002 of providing a substrate. The method 1000 proceeds to operation 1004 of forming channel layers and sacrificial layers alternatively stacked on top of one another. The method 1000 proceeds to operation 1006 of defining a number of semiconductor stacks. The method 1000 proceeds to operation 1008 of forming a number of dummy gate structures traversing the semiconductor stacks. The method 1000 proceeds to operation 1010 of forming source and drain structures. The method 1000 proceeds to operation 1012 of replacing the dummy gate structures with respective active structures. The method 1000 proceeds to operation 1014 of forming a number of gaps to cut the active gate structures each into a number of gate segments. Such gaps may be defined according to the gaps 151A-B, 152A-B, 153A-C, 154A-C, 155A-B, 156A-B, 157A-C, 158A-C, 159A-B, and 160A-B of the layout 100, the gaps 551A-B, 552A-B, 553A-B, 554A-B, 555A, 556A, 557A, 558A, 559A, 560A, 561A, 562A, 563A, 564A, 565A, 566A, 567A-B, 568A-B of the layout 500, the gaps 651A-B, 652A-B, 653A-C, 654A-C, 655A-C, 656A-C, 657A-B, 658A-B, 659A-B, 660A-B, 661A-C, 662A-C, 663A-B, 664A-B, 665A-C, 666A-C, 667A-C, 668A-C of the layout 600, the gaps 771 to 779 of the layout 700, and the gaps 871 to 875 of the layout 800 described in FIGS. 1, 5, 6, 7, and 8, respectively. The method 1000 proceeds to operation 1016 of forming interconnect structures.

In one aspect of the present disclosure, a semiconductor device is disclosed. The semiconductor device includes a Read Only Memory (ROM) array comprising a plurality of transistors arranged over a plurality of rows and a plurality of columns. The plurality of rows correspond to a plurality of active regions that continuously extend along a first lateral direction, respectively, and the plurality of columns correspond to a plurality of gate structures that discontinuously extend along a second lateral direction, respectively, the first lateral direction and the second lateral direction being perpendicular to each other. At least a first one of the plurality of gate structures comprising a first gap cutting the first gate structure and at least a second one of the plurality of gate structures comprising a second gap cutting the second gate structure are disposed immediately next to each other along the first lateral direction. The first gap and an extension of the second gap are offset from each other along the second lateral direction.

In another aspect of the present disclosure, a semiconductor device is disclosed. The semiconductor device includes a plurality of active regions parallel with one another, the plurality of active regions extending along a first lateral direction. The semiconductor device includes a plurality of gate structures parallel with one another, the plurality of gate structures extending along a second lateral direction perpendicular to the first lateral direction, wherein each of the plurality of gate structures comprises one or more discrete segments physically separated by respective gaps. At least a first one of the plurality of gate structures comprises a first segment overlaying a first number of the plurality of active regions, and at least a second one of the plurality of gate structures, disposed adjacent the first gate structure, comprises a second segment overlaying a second number of the plurality of active regions. The first segment is shifted away from the second segment along the second lateral direction.

In yet another aspect of the present disclosure, a method for fabricating memory devices is disclosed. The method includes forming a plurality of active regions parallel with one another, wherein the plurality of active regions extend along a first lateral direction. The method includes forming a plurality of gate structures parallel with one another, wherein the plurality of gate structures extend along a second lateral direction perpendicular to the first lateral direction, wherein each of the plurality of gate structures overlays the plurality of active regions. The method includes separating each of the plurality of gate structures into a respective set of discrete segments. At least a first one of the plurality of gate structures comprises a first segment, and at least a second one of the plurality of gate structures, disposed adjacent the first gate structure, comprises a second segment. The first segment is shifted away from the second segment along the second lateral direction.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a Read Only Memory (ROM) array comprising a plurality of transistors arranged over a plurality of rows and a plurality of columns;
wherein the plurality of rows correspond to a plurality of active regions that continuously extend along a first lateral direction, respectively, and the plurality of columns correspond to a plurality of gate structures that discontinuously extend along a second lateral direction, respectively, the first lateral direction and the second lateral direction being perpendicular to each other;
wherein at least a first one of the plurality of gate structures comprising a first gap cutting the first gate structure and at least a second one of the plurality of gate structures comprising a second gap cutting the second gate structure are disposed immediately next to each other along the first lateral direction; and
wherein the first gap and an extension of the second gap are offset from each other along the second lateral direction.

2. The semiconductor device of claim 1, wherein the first gap and the second gap are offset from each other along the second lateral direction with two of the plurality of active regions.

3. The semiconductor device of claim 1, wherein the first gap and the second gap are offset from each other along the second lateral direction with one of the plurality of active regions.

4. The semiconductor device of claim 1, wherein the first gap and the second gap are offset from each other along the second lateral direction with four of the plurality of active regions.

5. The semiconductor device of claim 1, wherein the first gate structure comprises a third gap cutting the first gate structure, the first gap and the third gap being symmetric with respect to the extension of the second gap along the second lateral direction.

6. The semiconductor device of claim 1, wherein the first gate structure comprises a third gap cutting the first gate structure, the third gap and the second gap being aligned with each other along the first lateral direction.

7. The semiconductor device of claim 1, wherein the first gate structures comprises a third gap cutting the first gate structure, the first gap and the third gap being asymmetric with respect to the extension of the second gap along the second lateral direction.

8. The semiconductor device of claim 1,
wherein at least a third one of the plurality of gate structures, comprising a third gap cutting the third gate structure, is disposed opposite the first gate structure from the second gate structure along the first lateral direction, and at least a fourth one of the plurality of gate structures, comprising a fourth gap cutting the fourth gate structure, is disposed opposite the second gate structure from the first gate structure along the first lateral direction;
wherein the first gap and the third gap are aligned with each other along the first lateral direction; and
wherein the second gap and the fourth gap are aligned with each other along the first lateral direction.

9. The semiconductor device of claim 8,
wherein the first gate structure further comprises a fifth gap cutting the first gate structure, and the third gate structure further comprises a sixth gap cutting the third gate structure; and
wherein the fifth gap and the sixth gap are aligned with each other along the first lateral direction.

10. The semiconductor device of claim 9, wherein the first gap and the fifth gap are symmetric with respect to the extension of the second gap along the second lateral direction.

11. The semiconductor device of claim 9, wherein a segment of the first gate structure cut by the first gap and the fifth gap overlays a plural number of the active regions.

12. A semiconductor device, comprising:
a plurality of active regions parallel with one another, the plurality of active regions extending along a first lateral direction; and
a plurality of gate structures parallel with one another, the plurality of gate structures extending along a second lateral direction perpendicular to the first lateral direction, wherein each of the plurality of gate structures comprises one or more discrete segments physically separated by respective gaps;
wherein at least a first one of the plurality of gate structures comprises a first segment overlaying a first number of the plurality of active regions, and at least a second one of the plurality of gate structures, disposed adjacent the first gate structure, comprises a second segment overlaying a second number of the plurality of active regions;
wherein the first segment is shifted away from the second segment along the second lateral direction.

13. The semiconductor device of claim 12, wherein the first number is equal to the second number.

14. The semiconductor device of claim 12, wherein the first number is different from the second number.

15. The semiconductor device of claim 12, wherein an intersection of each of the plurality of active regions and a corresponding one of the plurality of gate structures form a Read-Only-Memory (ROM) cell.

16. The semiconductor device of claim 12, wherein the first segment is shifted away from the second segment along the second lateral direction with a third number of the plurality of active regions.

17. The semiconductor device of claim 16, wherein the first number, second number, and third number are each an integer equal to or greater than 1.

18. The semiconductor device of claim 12,
wherein each of the plurality of active regions and a corresponding subset of the plurality of gate structures operatively form a plurality of transistors of a Read Only Memory (ROM) array;
wherein a first subset of the plurality of transistors have a first threshold voltage, and a second subset of the plurality of transistors have a second threshold voltage different from the first threshold voltage;
wherein a number of the first subset of transistors is equal to a number of the second subset of transistors.

19. A method for fabricating memory devices, comprising:
forming a plurality of active regions parallel with one another, wherein the plurality of active regions extend along a first lateral direction;
forming a plurality of gate structures parallel with one another, wherein the plurality of gate structures extend along a second lateral direction perpendicular to the first lateral direction, wherein each of the plurality of gate structures overlays the plurality of active regions; and
separating each of the plurality of gate structures into a respective set of discrete segments;
wherein at least a first one of the plurality of gate structures comprises a first segment, and at least a second one of the plurality of gate structures, disposed adjacent the first gate structure, comprises a second segment;
wherein the first segment is shifted away from the second segment along the second lateral direction.

20. The method of claim 19,
wherein each of the plurality of active regions and a corresponding subset of the plurality of gate structures operatively form a plurality of transistors of a Read Only Memory (ROM) array;
wherein a first subset of the plurality of transistors have a first threshold voltage, and a second subset of the plurality of transistors have a second threshold voltage different from the first threshold voltage;
wherein a number of the first subset of transistors is equal to a number of the second subset of transistors.
